(19) United States
(12) Patent Application Publication
(10) Pub. No.: US 2007/0109829 A1
(43) Pub. Date: May 17, 2007

(54) Dynamic time sequence control device and its method for word matching circuit

(75) Inventors: Chi-Sheng Lin, Cingshuei Township (TW); Chun-Ming Huang, Hsinchu City (TW); Lan-Da Van, Miao-Li (TW); Nien-Hsiang Chang, Taichung (TW); Chun-Pin Lin, Banciao City (TW); Chih-Hsien Hsu, Taoyuan City (TW); Chau-Chin Wang, Taipei (TW)

Correspondence Address: BIRCH STEWART KOLASCH & BIRCH, PO BOX 747, FALLS CHURCH, VA, 22040-0747, US

(73) Assignee: NATIONAL CHIP IMPLEMENTATION CENTER

(21) Appl. No.: 11/272,690

(22) Filed: Nov. 15, 2005

(51) Int. Cl. G11C 15/00

(52) U.S. Cl. 365/49

(57) ABSTRACT

A dynamic time sequence control device and its method for a word matching circuit. The word matching circuit includes a first switch connected between an input voltage and a node to respond to a control signal generated by a pre-charging circuit so that within a pre-charging phase period a current is generated to flow through a capacitor to generate a charging voltage. The node is connected to multiple data memories and matching circuits so that the matching result can be outputted through the node. The dynamic time sequence control device includes a second switch connected between the first switch and the node. A third switch is connected between the data memory and matching circuit and a self time sequence controller has a threshold value to respond to the control signal and to conduct the second switch and turn off the third switch during the pre-charging phase period, meanwhile, it turns off the second switch and conducts the third switch when the charging voltage is detected to be larger than threshold value. The self time sequence controller detects the output voltage of the node and outputs the data matching result during a value-acquisition phase period.

A dynamic time sequence control device and its method for word matching circuit A dynamic time sequence control device and its method for word matching circuit, the word matching circuit comprising of a first switch connected in between an input voltage and a node to respond to a control signal generated by a pre-charging circuit so that within a pre-charging phase period a current is generated to flow through a capacitor to generate a charging voltage, the node is connected to multiple data memories and matching circuits so that the matching result can be outputted through the node, the dynamic time sequence control device comprising of a second switch connected in between the first switch and the node; a third switch connected in between the data memory and matching circuit; and a self time sequence controller comprising of a threshold value to respond to the control signal and to conduct the second switch and turn off the third switch during the pre-charging phase period, meanwhile, it turns off the second switch and conducts the third switch when the charging voltage is detected to be larger than threshold value; wherein the self time sequence controller detects the output voltage of the node and outputs the data matching result during a value-acquisition phase period.

### FIELD OF THE INVENTION

This invention relates to a content-addressable memory, it specifically relates a dynamic time sequence control device and its method for word matching circuit of content-addressable memory.

### PRIOR ART

A word matching unit of content-addressable memory (CAM) is to perform data matching on data stored in the address of the memory, meanwhile, the address of the stored data which matches the input data after matching will be outputted to address output port in order to indicate data stored in that address matches input data.

In the data matching process performed by word matching circuit, pre-charging phase and value-acquisition phase operation will be performed respectively, logic function will be used to realize matching result. In pre-charging phase operation, word matching circuit is to charge a word matching node to input voltage VDD and to check if input data matches stored data in the value-acquisition operation so as to decide if the input voltage VDD charged at word matching node should be discharged to ground end GND level. In the value-acquisition phase operation, when input data does not match stored data, voltage on word matching node will be discharged form input voltage VDD to ground end GND level which leads to dynamic power dissipation. In the execution of data matching, only one stored data will match input data, other stored data won't match input data, therefore, circuit will dissipate large dynamic power. In the design of word matching circuit, data memory and matching circuit are used to perform a matching between input data and stored data, meanwhile, data memory and matching circuit adopts a method using the matching result to output a control to pull down a transistor so as to reflect the data matching result, when the input data does not match stored data, then during the pre-charging phase period performed by word matching circuit, a short circuit current from the input voltage VDD to ground end GND will be generated, which in turn generate static power dissipation.

In the prior art word matching circuit, same pre-charging phase time and value-acquisition phase time are adopted, that is, synchronous signal operation is adopted. However, due to process parameter variation and global control signal skew, characteristic of word matching circuit will be affected, therefore, the time needed and power dissipated by the word matching circuit during pre-charging phase and value-acquisition operation will be increased.

In order to reduce the power dissipation of word matching circuit, in an U.S. Pat. No. 6,822,886, Regev uses a reduction on voltage level swing of matching node to reduce dynamic power dissipation of circuit during data matching process. Through the use of an externally added Negative Voltage Level (NRV) as charging voltage, when word matching circuit performs pre-charging phase, it will charge voltage on matching node to this externally added negative voltage level. Since the externally added negative voltage level is between supply input voltage VDD and ground voltage GND, therefore, voltage level swing of matching node will be limited to between negative voltage level and ground voltage GND, the dynamic power dissipation of the circuit is thus reduced. However, since the output sensor amplifier characteristic in each word matching circuit is different, in addition, the word matching circuit characteristic could be changed by different working environments, therefore, the best negative voltage level can not be decided precisely. Furthermore, externally added negative voltage level will limit the flexibility of circuit application, it thus needs very precise negative voltage level during circuit application, in addition, static power dissipation will exist in the circuit.

In order to prevent the adoption of externally added voltage supply method, an article in the journal of JSSC 2003“A ternary content-addressable memory (TCAM) based on 4 T static storage and including a current-race sensing scheme” published by Arsovski et al. has adopted current speed competition method in order to effectively reduce the voltage level swing of matching node. Since the current speed competition method only needs to limit the maximum level of matching node to recognizable range, therefore, it can reduce charging time of the circuit and dynamic power dissipation, meanwhile, the static power dissipation caused by short circuit current relative to the ground can be reduced. However, in order to prevent process shift, when the voltage level of matching node is charged to recognizable high level, a time delay controller should be used to charge a bit additional time to ensure the maintaining at recognizable logic 1 level of the word matching circuit output of same data matching, static power and dynamic power are thus dissipated at the same time and the pre-charging phase time will be increased, moreover, the design of time delay controller is highly dependent on process and operation temperature, the reliability and stability of circuit design is thus reduced, meanwhile, static power dissipation exists in the circuit.

### SUMMARY OF THE INVENTION

The purpose of this invention is to provide a dynamic time sequence control device and its method in order to reduce the power dissipation of word matching circuit.

According to one embodiment of the current invention, in a word matching circuit, a first switch is connected in between an input voltage and a node to respond to a control signal to turn on and turn off a first switch to generate a current during a pre-charging phase and a value-acquisition phase period respectively, the current flow through a capacitor to generate a charging voltage, the node is connected to multiple data memories and matching circuits in order to perform data matching, when the data matching result shows correct, the node will output the voltage level of the charging voltage, when the data matching shows wrong, it will discharge toward the capacitor, an effective data record circuit will detect the data memory and matching circuit so that an effective flag can be generated when there is an effective data stored in the data memory and the matching circuit, the effective flag is connected to a pre-charging circuit to generate the control signal, a dynamic time sequence control device comprising of a second switch connected in between the first switch and the capacitor, a third switch connected in between the data memory and the matching circuit to form a discharge path to the capacitor; and a self time sequence controller comprising of a threshold value to respond to the control signal and to conduct the second switch and turn off the third switch in the pre-charging phase period, meanwhile, it turns off the second switch and conducts the third switch when the charging voltage is detected to be larger than threshold value; wherein the self time sequence controller detects the output voltage of the node and outputs the data matching result during a value-acquisition phase period.

### BRIEF DESCRIPTION OF THE DRAWINGS

For those who skilled in the art, the following detailed descriptions accompanied with the drawings can make the current invention more clearly understood, the above-mentioned and other goals and purposes will become more obvious, wherein:

FIG. 1 is a circuit diagram for a word matching circuit having dynamic time sequence control device;

FIG. 2 is a structure illustration of a self time sequence controller;

FIG. 3 is an output simulation waveform diagram under an input supply voltage of VDD=1.8 V for the word matching circuit 10 of FIG. 1.

### SYMBOL DESCRIPTIONS

10 word matching circuit
12 first switch
14 node
16 capacitor
18 pre-charging circuit
20 data memory and matching circuit
202 bit storage device
204 NMOS switch
22 effective data record circuit
222 effective bit recorder
224 NMOS switch
24 second switch
26 third switch
28 self time sequence controller
282 lock
284 sensor amplifier

### Embodiments

In order to enhance data matching speed of word matching circuit of content addressable memory and to reduce static and dynamic power dissipation, this invention proposes a dynamic time sequence control device and its method for word matching circuit, it detects voltage level at matching node of word matching circuit in the pre-charging phase period, when the voltage level is greater than a threshold value, stops the charging of matching node and performs operation of value-acquisition phase to effectively reduce the static and dynamic power dissipation and to enhance the data matching effectiveness of word matching circuit.

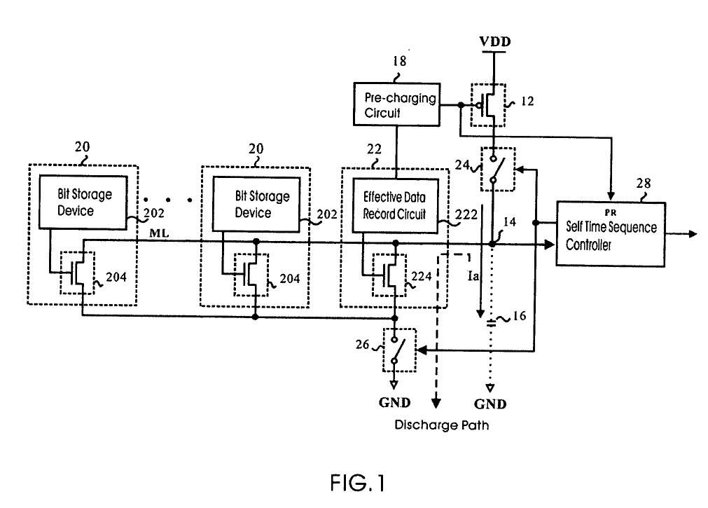

FIG. 1 is a word matching circuit 10 having a dynamic time sequence control device comprising of a first switch 12 which is a PMOS switch connected in between an input voltage VDD and a node 14, a capacitor 16 connected in between a node 14 and a ground end GND, gate electrode of first switch 12 is connected to a pre-charging circuit 18, the pre-charging circuit 18 will generate a control signal to turn on and turn off a first switch 12 in a pre-charging phase period and a value-acquisition phase period respectively, in turning on a first switch 12, current 1a will be generated to flow through capacitor 16 to generate a charging voltage, multiple data memories and matching circuits 20 connect node 14, each data memory and matching circuit 20 comprises of a bit storage device 202 and a NMOS switch 204, each bit storage device 202 stores one data to be matched to input data, each NMOS switch 204 is connected in parallel and connected to node 14, when the data matching result shows correct, bit storage unit 202 will control NMOS switch 204 to turn off so that the voltage at node 14 will maintain at charging voltage level, on the other hand, when the data matching shows wrong, bit storage device 202 will control NMOS switch 204 to turn on so that capacitor 16 will generate a discharge path, an effective data record circuit 22 connects node 14, it comprises of an effective bit recorder 222 and a NMOS switch 224, the effective bit recorder 222 is to detect if the data stored in the multiple data memories and matching circuits 20 effective, if the data stored in the data memory and matching circuit 20 is ineffective, the effective bit recorder 222 will then output an ineffective flag to pre-charging circuit 18, the control signal will be used to turn off first switch 12 and control NMOS switch 224 to turn off, capacitor 16 will then generate discharge path to let the node voltage maintain at a low potential, if the stored data is effective, then the effective bit recorder 222 will output a flag to pre-charging circuit 18, the pre-charging circuit 18 can then control the turn on or off of the first switch 12 to perform data matching, a second switch 24 connected in between first switch 12 and node 14, a third switch 26 connected in between data memory and matching circuit 20 and ground end GND, the first switch 24 and 26 are turned on and off respectively during the pre-charging phase, a self time sequence controller 28 comprising of a threshold value, it receives control signal from the pre-charging circuit 18 so as to detect the node voltage level in the pre-charging phase period, that is to detect the charging voltage of capacitor 16, turn off second switch 24 and turn on third switch 26 when the node voltage level is greater than the threshold value, meanwhile, during value-acquisition period, the second switches 24 and 26 are maintained at off and on status respectively, at this moment, self time sequence controller 28 will detect the voltage level at the node in order to output the data matching result at data memory and matching circuit 20.

If the data matching result shows correct, node 14 will maintain at threshold value level, it can thus be seen as logic function 1, if the matching result shows incorrect, the NMOS switch 204 will be turned on so that capacitor 16 will generate a discharge path through third switch 26 so that the voltage at node 14 is at ground end GND level, it can be seen as logic function 0. Node 14 is the matching node in the word matching circuit 10, in the value-acquisition phase period, the voltage level at node 14 is used as data matching result.

Second switch 24 and 26 and self time sequence controller 28 form a dynamic time sequence control device of the current invention, during pre-charging phase period, since the node voltage level is controlled at the threshold value set by self time sequence controller 28, generally, the critical value is designed at value smaller than the input voltage VDD, therefore, the charging voltage of capacitor 16 will not be charged to input voltage VDD, that is, to reduce the voltage swing at node 14 so that the dynamic power dissipation at word matching circuit 10, meanwhile, a third switch 26 is connected underneath all the in-parallel connected NMOS switch 204 and NMOS switch 224, turn off the third switch during pre-charging phase period, this can effectively avoid the static power dissipation resulted from the short circuit current relative to the ground end GND during the execution of pre-charging phase, the design of low power word matching circuit can thus be realized.

Please refer to FIG. 1, in order to avoid the sudden short circuit current due to the simultaneous conducting of first switch 12 and NMOS switch 20 and second switch 24 and 26, a signal delay buffer (not shown in the figure) can be added in between self time sequence controller 28 and third switch 26 to increase the control signal delay, therefore, word matching circuit can turn off the second switch 24 first and then turn on the third switch 26, this can prevent the sudden short circuit current power dissipation due to the conversion of the circuit from pre-charging phase to value-acquisition phase.

Second switch 24 can be designed by PMOS, third switch 26 can be designed by NMOS switch or a reverse control signal delay connected to the gate electrode of PMOS switch, or realized by other method. When third switch 26 is designed by reverse control signal delay and PMOS switch, in the value-acquisition phase period, if the stored data does not match input data, the voltage level at node 14 will discharge to the conducting cut-in voltage Vt of the PMOS switch, the voltage swing at node 14 will then be effectively reduced in order to reduce dynamic power dissipation, meanwhile, the threshold value should be designed to be larger than the conducting cut-in voltage Vt of PMOS switch, if the third switch 26 is designed by NMOS switch, then the threshold value can be designed to be larger than the level at ground end GND.

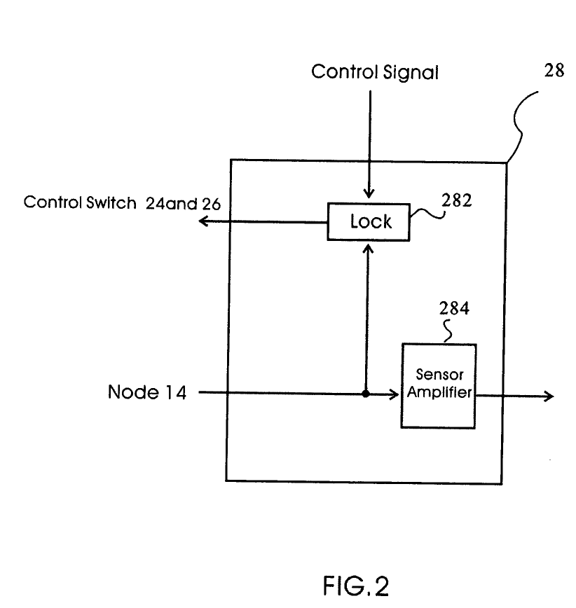

FIG. 2 is an illustration of self time sequence controller 28. The self time sequence controller 28 comprising of a lock 282 and a sensor amplifier 284, lock 282 is to detect the control signal generated by pre-charging circuit 18 so that the voltage level at node 14 during pre-charging phase period can be detected, when it is greater than critical value, second switch 24 is controlled to be turn off and third switch 26 is controlled to be turned on so that the voltage level at node 14 during value-acquisition phase period is detected by the sensor amplifier 284, and correct data matching result can be outputted.

For self time sequence control method in the current invention, first, the control signal generated by pre-charging circuit 18 is detected in order to verify whether the word matching circuit is performing pre-charging or value-acquisition phase. During the pre-charging phase period, second switch 24 is turned on and third switch 26 is turned off, meanwhile, the voltage level at node 14 is detected, when the output charging voltage level at node 14 reaches the threshold value, second switch 24 is controlled to be turned off and third switch 26 is controlled to be turned on and perform value-acquisition phase, the above-mentioned steps are mainly executed by lock 282. During value-acquisition phase period, the voltage level at node 14 is detected in order to output the data matching result in multiple data memories and matching circuits 20, this action is mainly performed by sensor amplifier 284. The self time sequence control method in the current invention can inhibit the charging voltage level at node 14, the circuit speed and power dissipation is found to be greatly improved, meanwhile, under global control signal, this can prevent the low circuit effectiveness due to the instability in process parameters or operation temperature, or even the circuit error action can be prevented.

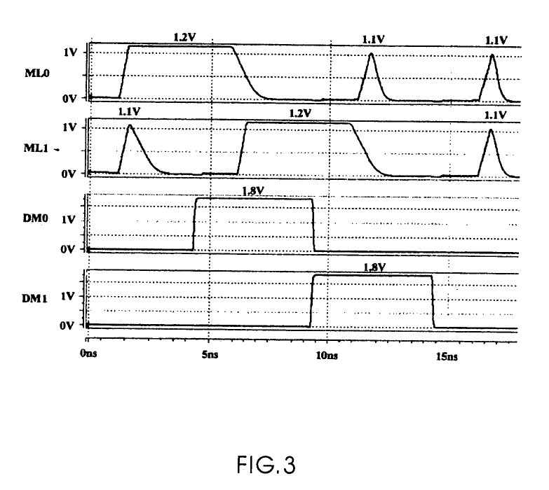

FIG. 3 is an output simulation waveform diagram under an input supply voltage of VDD=1.8 V for the word matching circuit 10 of FIG. 1. The two waveforms ML0 and ML1 in FIG. 3 represent two voltage levels at node 14 respectively, however, two waveforms DM0 and DM1 represent the two output voltage levels outputted respectively by self time sequence controller 28.

From the output waveform in FIG. 3 we know that when the input data in data memory and matching circuit 20 matches the stored data, the voltage at node 14 will remain at certain voltage level, in FIG. 3, this is 1.2 V, when the input data does not match stored data, the waveform due to voltage at node 14 will be like a surge, its voltage level will not be larger than 1.1 V. Since most of the matching between stored data and input data shows mismatch, therefore, the voltage level at node 14 is mostly remained below 1.1 V, during the data matching, node 14 will reduce dynamic power dissipation due to lower voltage charging level. The voltage at node 14 is 1.2 V when the data match result shows matched, however, sensor amplifier 284 at self time sequence controller 28 will amplify the voltage level at node 14 when it detects the voltage at node 14 so that the output signal at self time sequence controller 28 will reach the output voltage VDD level, as shown in FIG. 3, if the data matching result shows matched, the voltage levels at DM0 and DM1 will reach 1.8 V, that is, the voltage level of input voltage VDD.

The descriptions above for the better embodiment of the current invention is just for clarification purpose, it is not meant to limit the disclosure format of the current invention, any modification is possible based on the above instruction or the above embodiment of the current invention, the embodiment is used to explain the principle behind the current invention and to let people who are familiar with this technology to select and describe the current invention in practical application, the technological concept and purpose of this invention should be determined by the following claims.

What is claimed is:

1. A dynamic time sequence control device for word matching circuit, the word matching circuit comprising of a first switch connected in between an input voltage and a node to respond to a control signal and to turn on and turn off the first switch and to generate a current in a pre-charging phase period and a value-acquisition period respectively, the current flows through a capacitor to generate a charging voltage, the node is connected to multiple data memories and matching circuits to perform data matching, when the data matching shows matched, the node will output the voltage level of the charging voltage, when the data matching shows mismatched, it will discharge to the capacitor, an effective data record circuit will detect the data memory and matching circuit so that an effective flag can be generated when there is an effective data stored in the data memory and the matching circuit, the effective flag is connected to a pre-charging circuit to generate the control signal, the dynamic time sequence control device comprising of:
a second switch connected in between the first switch and the capacitor;
a third switch connected to the data memory and matching circuit so as to form a discharge circuit to the capacitor; and
a self time sequence controller, comprising of a threshold value to respond to the control signal and to conduct the second switch and turn off the third switch during the pre-charging phase period, meanwhile, it turns off the second switch and conducts the third switch when the charging voltage is detected to be larger than threshold value;
wherein the self time sequence controller will detect the voltage level at the node during the value-acquisition period in order to output the data matching result.

2. The dynamic time sequence control device of claim 1 wherein the self time sequence controller comprising of:
a lock to detect the control signal so that the second switch and third switch can be turned on during the pre-charging phase period and when the charging voltage is detected to be larger than threshold value to turn off the second switch and conduct the third switch; and
a sensor amplifier to detect the voltage level at the node and to output the matching result.

3. The dynamic time sequence control device of claim 1 wherein the critical value is smaller than the input voltage.

4. The dynamic time sequence control device of claim 1 wherein the second and the third switch is a PMOS switch and a NMOS switch respectively.

5. The dynamic time sequence control device of claim 1 wherein the second and third switch is PMOS switch and a gate electrode having reverse control signal delay connected to another PMOS switch.

6. The dynamic time sequence control device of claim 1 further comprising of a signal delay buffer connected in between the self time sequence controller and the third switch.

7. A dynamic time sequence control method for word matching circuit wherein the word matching circuit comprising of a first switch connected in between an input voltage and a node to respond to a control signal to turn on and turn off a first switch to generate a current during a pre-charging phase and a value-acquisition phase period respectively, the current flow through a capacitor to generate a charging voltage, the node is connected to multiple data memories and matching circuits in order to perform data matching, when the data matching result shows correct (matched), the node will output the voltage level of the charging voltage, when the data matching shows wrong (mismatched), it will discharge toward the capacitor, an effective data record circuit will detect the data memory and matching circuit so that an effective flag can be generated when there is an effective data stored in the data memory and the matching circuit, the effective flag is connected to a pre-charging circuit to generate the control signal, the dynamic time sequence control method comprising of the following steps:
define a threshold value;
detect the control signal to turn on the second switch connected in between the first switch and the capacitor during the pre-charging phase period, and turn off a third switch connected to the data memory and matching circuit;
detect the voltage level at the node so as to turn off the second switch and turn on the third switch when the charging voltage reaches the threshold value and to enter the value-acquisition phase period; and
detect the voltage level at the node in order to output the data matching result.

8. The dynamic time sequence control method of claim 7 wherein the step of detecting the control signal is done by a lock.

9. The dynamic time sequence control method of claim 7 wherein the step of detecting the voltage level at the node in order to output the data matching result is done by a sensor amplifier.

10. A word matching circuit having dynamic time sequence control device, comprising of:
a first switch, connected in between an input voltage and a node to respond to a control signal to turn on and turn off a first switch to generate a current during a pre-charging phase and a value-acquisition phase period respectively;
a capacitor, connected to the node so that current will flow through the capacitor to generate a charging voltage;
the node is connected to multiple data memories and matching circuits in order to perform data matching, when the data matching result shows correct, the node will output the voltage level of the charging voltage, when the data matching shows wrong, it will discharge toward the capacitor;
an effective data record circuit to detect the data memory and matching circuit, it will generate an effective flag or an ineffective flag when an effective data or an ineffective data is stored in the data memory and the matching circuit;
a pre-charging circuit connected to the effective data record circuit, it will generate the control signal when the effective flag is received, it will turn off the first switch when an ineffective flag is received; and
a dynamic time sequence control device, comprising of:
a first switch, connected in between the first switch and the capacitor;
a second switch, connected to the data memory and matching circuit in order to form a discharge circuit with the capacitor; and
a self time sequence controller having a threshold value to respond to the control signal, during the pre-charging phase period, it will conduct the first switch and turn off the second switch, meanwhile, it turns off the first switch and conducts the second switch when the charging voltage is detected to be larger than threshold value;
wherein the self time sequence controller detects the output voltage of the node and outputs the data matching result during a value-acquisition phase period.

11. The word matching circuit of claim 10 wherein the self time sequence controller comprising of:
a lock, to detect the control signal and to turn on the second switch and turn off the third switch during the pre-charging phase period, meanwhile, it turns off the second switch and conducts the third switch when the charging voltage is detected to be larger than threshold value; and
a sensor amplifier to detect the voltage level at the node in order to output the data matching result.

12. The word matching circuit of claim 10 wherein the threshold value is smaller than the input voltage.

13. The word matching circuit of claim 10 wherein the second and the third switches are a PMOS switch and a NMOS switch respectively.

14. The word matching circuit of claim 10 wherein the second and the third switches are PMOS switch and a gate electrode with reverse control signal delay connected to another PMOS switch.

15. The word matching circuit of claim 10 wherein the dynamic time sequence control device comprising of a signal delay buffer connected in between the self time sequence controller and the third switch.

16. The word matching circuit of claim 10 wherein the data memory and matching circuit comprising of:
a NMOS switch, connected in between the node and the third switch; and
a bit storage device used to store data and to match with input data so that when the matching is correct the NMOS switch is turned off and when the matching is incorrect the NMOS switch is turned on.
